(19) United States
(12) Patent Application Publication
(10) Pub. No.: US 2017/0247794 A1
(43) Pub. Date: Aug. 31, 2017

(54) SINGLE CHAMBER MULTI-PARTITION DEPOSITION TOOL AND METHOD OF OPERATING SAME

(71) Applicant: SANDISK TECHNOLOGIES LLC, Plano, TX (US)

(72) Inventors: Yusuke MUKAE, Yatomi (JP); Fumitaka AMANO, Yokkaichi (JP); Naoki TAKEGUCHI, Nagoya (JP)

(21) Appl. No.: 15/219,571

(22) Filed: Jul. 26, 2016

Related U.S. Application Data
(60) Provisional application No. 62/299,621, filed on Feb. 25, 2016.
(60) Provisional application No. 62/316,647, filed on Apr. 1, 2016.

(51) Int. Cl. C23C 16/455

(52) U.S. Cl. CPC C23C 16/45527; C23C 16/45544

(57) ABSTRACT

A process chamber includes multiple partitions within a single continuous vacuum enclosure. Each of the multiple partitions is defined by respective distinct volumes within the single continuous vacuum enclosure that are connected thereamongst for unhindered movement of a substrate therethrough. The multiple partitions are configured to provide different process gases or purge gases to the substrate as the substrate cycles through the multiple positions. The process can cycle through a first deposition step that deposits a first material on the substrate in a first position and a second deposition step that deposits a second material on the substrate in a second position within each cycle. Alternatively or additionally, the process spaces can include at least one precursor treatment space and at least one reaction space.

### FIELD

The present disclosure relates generally to the field of semiconductor processing tools, and specifically to a single chamber multi-partition deposition tool, and methods of operating the same.

### BACKGROUND

Many semiconductor devices employ a stack of repeated material compositions. For example, an alternating stack of first material layers and second material layers can be employed in three-dimensional memory devices such as resistive random access memory (ReRAM) devices and vertical NAND memory devices. In an illustrative example, ReRAM devices can employ an alternating stack of word lines and insulating layers. A metal layer can be employed for each word line and a dielectric material layer such as a silicon oxide layer can be employed for each insulating layer. In case an alternating stack of metal lines and silicon oxide lines is employed, such an alternating stack is referred to as an OMOM stack.

An alternating stack of first material layers and second material layers can be formed employing multiple process chambers. A first process chamber having a first vacuum enclosure is employed for deposition of insulating layers, and a second process chamber having a second vacuum enclosure is employed for deposition of metal layers. A transfer chamber and/or a slit valve system can be provided to separate process gases of the two process chambers. However, this system has an inherently low throughput because a significant portion of the processing time is wasted while one of the two deposition chambers remains idle. Further, operation of slit valves and transfer of a substrate between the two process chambers can take significant time.

In case an absorption chamber and a reaction chamber are employed to deposit a film, transfer between the two chambers and thermal stabilization after transfer into each chamber can take significant time. Time spent for substrate transfer or thermal stabilization can increase overall processing time needed to deposit a film, resulting in low throughput of a deposition system.

### SUMMARY

According to an aspect of the present disclosure, a reactor system comprising multiple partitions within a single continuous vacuum enclosure is provided. Each of the multiple partitions is defined by respective distinct volumes within the single continuous vacuum enclosure that are connected thereamongst for unhindered movement of at least one substrate therethrough. A first subset of the multiple partitions comprise processing spaces configured to provide a respective process gas that provides a process selected from adsorption and reaction (e.g., nitridation, oxidation or reduction). A second subset of the multiple partitions comprising purge spaces configured to provide a respective purge gas flow pattern therein between at least one respective purge gas inlet and a respective vacuum port and to provide isolation between process gases between a respective neighboring pair of processing spaces. At least one substrate carrier is configured to sequentially move through each of the multiple partitions in a cyclic pattern employing a sequence in which the processing spaces alternate with the purge spaces.

According to another aspect of the present disclosure, the reactor system of the present disclosure can be provided and operated by loading at least one substrate into the reactor system, and depositing at least one layer on each of the at least one substrate by moving the at least one substrate through each of the multiple partitions in the cyclic pattern employing the sequence.

According to another aspect of the present disclosure a method of making a device, comprises loading a substrate into a chamber of reactor system, and depositing by atomic layer deposition an alternating stack of instances of a first material layer and instances of a second material layer different from the first material layer on the substrate by moving the substrate through multiple processing spaces and purge spaces in the chamber in a cyclic pattern employing sequence in which the processing spaces alternate with the purge spaces.

### BRIEF DESCRIPTION OF THE DRAWINGS

FIG. 1A is a plan view of a first exemplary reactor system according to an embodiment of the present disclosure.

FIG. 1B is a vertical cross-sectional view of the reactor system along the curved vertical plane A-A′ in FIG. 1A.

FIG. 2 is a diagram illustrating an exemplary set of phases that can be employed to operate the reactor system of FIGS. 1A and 1B.

FIG. 3A is a vertical cross-sectional view of an exemplary film stack that can be formed employing the reactor system of FIGS. 1A and 1B. FIG. 3B shows a perspective view of a three dimensional ReRAM memory device containing the exemplary film stack of FIG. 3A.

FIG. 4A is a plan view of a second exemplary reactor system according to an embodiment of the present disclosure.

FIG. 4B is a vertical cross-sectional view of the second exemplary reactor system along the curved vertical plane A-A′ in FIG. 4A.

### DETAILED DESCRIPTION

As described above, the present disclosure is directed to a single chamber multi-partition deposition tool, and methods of operating the same, which are described below in detail.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a balance band within a band structure, or an n-type dopant that adds an electron to a conduction band within a band structure. As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material, i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

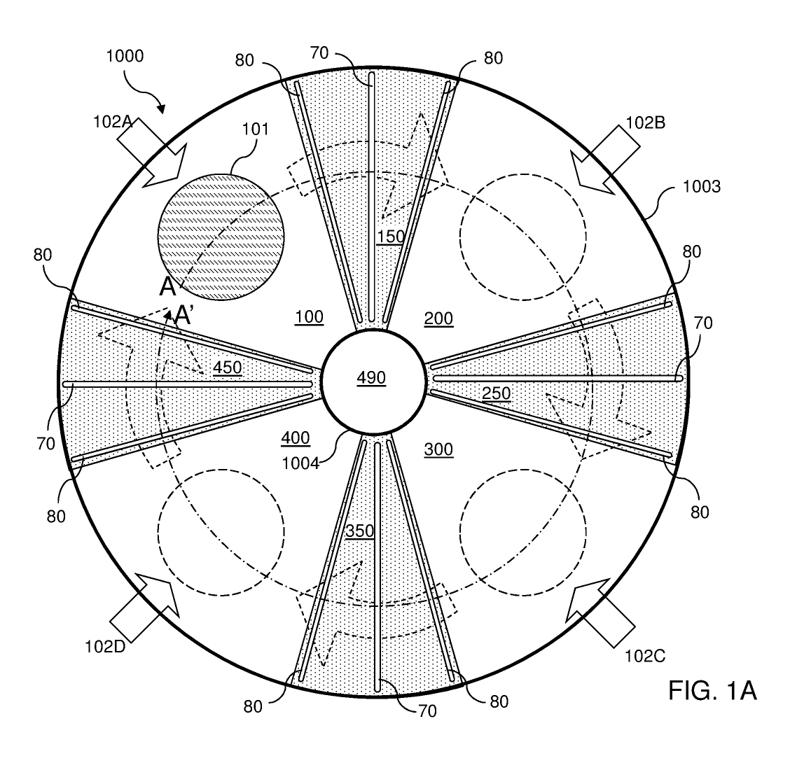

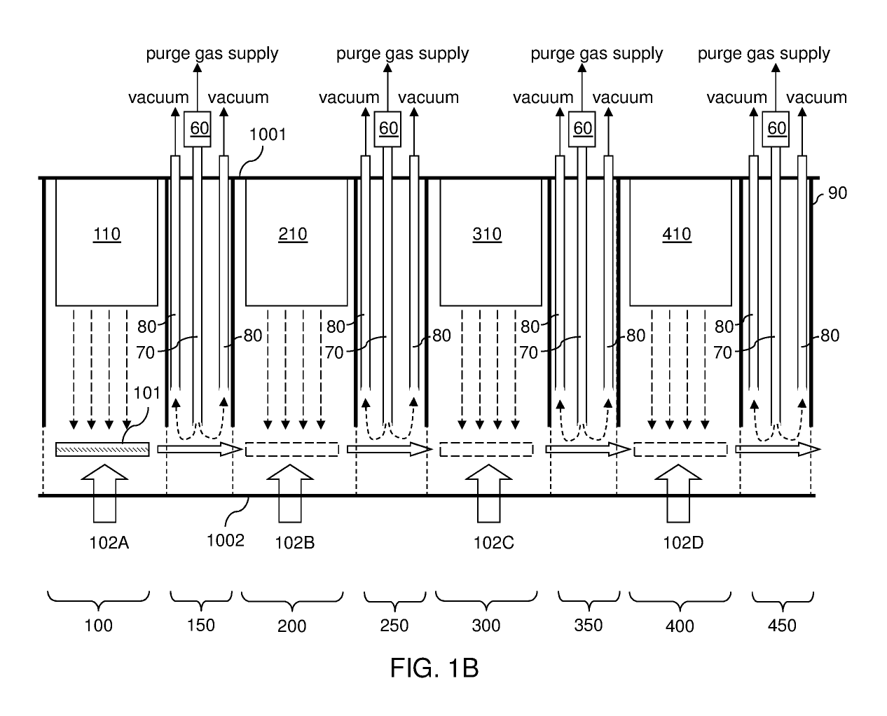

Referring to FIGS. 1A and 1B, a first exemplary reactor system 1000 is shown, which includes a single process chamber including multiple partitions (100, 200, 300, 400, 150, 250, 350, 450) for at least one substrate 101 to travel through. Each substrate 101 can be affixed (for example, by gravity or electrostatic force) to a respective substrate carrier (such as a chuck) that travels cyclically through the multiple partitions (100, 200, 300, 400, 150, 250, 350, 450). As used herein, a “partition” is defined as a fraction of a continuous volume that is less than the entire volume (e.g., a section of the total space in the single process chamber). The partition is connected to at least another partition to provide a free movement of material therebetween. The spatial extent of each partition can be defined by geometrical features (such as chamber sidewalls) and/or changes in ambient gas composition. As used herein, the term “partition” is used herein synonymously with the terms “space” and “volume” rather than to indicate a wall or a barrier.

The reactor system 1000 includes a vacuum enclosure, which can be a vacuum-tight space. As used herein, a “vacuum enclosure” refers to a volume that is physically isolated from a surrounding volume in a manner that enables sustained pressure differential between the vacuum enclosure and the surrounding volume. As used herein, a “sustained” pressure differential refers to a pressure differential that is maintained for a macroscopic time interval, i.e., greater than 1 second. In one embodiment, the vacuum enclosure can maintain 99% of an initial pressure differential between the vacuum enclosure and the surrounding volume after passage of 1 minute. In one embodiment, the vacuum enclosure can be connected to at least one vacuum pump, and can be configured to maintain a base pressure less than 100 mTorr, and preferably less than 1 mTorr, and even more preferably less than 1.0×10⁻⁶ Torr in the absence of any gas flow therein.

The vacuum enclosure may be defined by a combination of a top enclosure plate 1001 and a bottom enclosure plate 1002 that are vertically spaced from each other and adjoined to an outer sidewall 1003. Optionally, an inner sidewall 1004 extending between the top enclosure plate 1001 and the bottom enclosure plate 1002 can be provided within the outer sidewall 1003. In this case, the vacuum enclosure can be topologically homeomorphic to a torus. As used herein, an element is “topologically homeomorphic to a torus” if the element can be continuously stretched or shrunk to a torus without creating a new hole though a surface or eliminating a hole. In case the inner sidewall 1004 is not present, the vacuum enclosure can be topologically homeomorphic to a sphere. In this case, a vacuum pump may be connected to a center portion of the vacuum enclosure.

Optionally, substantially vertical sidewalls 90 that extend only partially between the top enclosure plate 1001 and the bottom enclosure plate 1002 can be provided. The substantially vertical sidewalls 90 may be adjoined to the top enclosure plate 1001 and not adjoined to the bottom enclosure plate 1002, or may be adjoined to the bottom enclosure plate 1002 and not adjoined to the top enclosure plate 1001. In this case, the partitions may be defined by the substantially vertical sidewalls 90 that extend vertically by distances that are less than the vertical spacing between the top enclosure plate 1001 and the bottom enclosure plate 1002. Gaps are provided between each neighboring pair of partitions for passage of the at least one substrate carrier and the at least one substrate thereupon. Each of the multiple partitions is defined by respective distinct volumes within the single continuous vacuum enclosure that are connected thereamongst for unhindered movement of at least one substrate therethrough.

In one embodiment, the reactor system 1000 can include a substrate carrier rotation mechanism 490 configured to rotate the at least one substrate carrier around a rotation axis located in a center portion of the reactor system. The multiple partitions can be located at different azimuthal angles around the rotation axis without any door or valve between neighboring pairs of partitions.

The multiple partitions (100, 200, 300, 400, 150, 250, 350, 450) can include a first subset that includes processing spaces (100, 200, 300, 400) and a second subset that includes purge spaces (150, 250, 350, 450). Each of the processing spaces (100, 200, 300, 400) is a partition configured to provide a respective process gas that provides a process selected from adsorption and reaction (e.g., nitridation, oxidation, or reduction). For example, the processing spaces (100, 200, 300, 400) can include a first processing space 100 configured to perform a first adsorption process, a second processing space 200 configured to perform a first reaction process (e.g., conversion of an adsorbed species by a nitridation, oxidation or reduction process to a layer) to form a first layer, a third processing space 300 configured to perform a second adsorption process, and a fourth processing space 400 configured to perform a second reaction process (e.g., nitridation, oxidation or reduction process) to form a second. Each of the purge spaces (150, 250, 350, 450) can be configured to provide a respective purge gas flow pattern therein between at least one respective purge gas inlet 70 and a respective vacuum port 80. Each of the at least one purge gas inlet 70 can be connected to a flow control device 60, which may be a mass flow controller (MFC) or an automatically actuated on/off valve. Each flow control device 60 can be connected to a purge gas supply, which can be a source of an inert gas such as argon or nitrogen. Each of the purge spaces (150, 250, 350, 450) can be configured to provide isolation between process gases between a respective neighboring pair of processing spaces (100, 200, 300, 400).

The purge spaces (150, 250, 350, 450) provide gas separation between neighboring pairs of processing spaces (100, 200, 300, 400), thereby preventing mixing of the process gases from neighboring processing spaces (100, 200, 300, 400). The substrate travels within a single chamber that defines a single continuous vacuum enclosure. In one embodiment, no door or valve is present within the single continuous vacuum enclosure, and the separation of process environment among the positions can be provided by the purge gas (such as argon or nitrogen gas) and the vacuum pumping at the gas separation areas.

In one embodiment, a single substrate carrier (e.g., a chuck) supporting a single substrate is employed within the process chamber. In another embodiment, multiple substrate carriers (e.g., multiple chucks) each supporting a respective substrate can be employed in the process chamber to process multiple substrates.

The at least one substrate carrier can be configured to sequentially move through each of the multiple partitions in a cyclic pattern employing a sequence in which the processing spaces (100, 200, 300, 400) alternate with the purge spaces (150, 250, 350, 450). For example, the purge spaces (150, 250, 350, 450) can include a first purge space 150 located between the first processing space 100 and the second processing space 200, a second purge space 250 located between the second processing space 200 and the third processing space 300, a third purge space 350 located between the third processing space 300 and the fourth processing space 400, and a fourth purge space 450 located between the fourth processing space 400 and the first processing space 100.

Each processing space (i.e., partition) (100, 200, 300, 400) can include a respective processing position (102A, 102B, 102C, 102D) for processing a substrate 101. A single substrate 101 or a plurality of substrates 101 can be loaded into the vacuum enclosure through an opening in the top enclosure plate 1001, though an opening in the bottom enclosure plate 1002, or through the outside sidewall 1003. The opening for passing one or more substrates 101 can be a valve that can provide a vacuum seal between the vacuum enclosure and the surrounding volume. Each substrate 101 can move through the various processing positions (102A, 102B, 102C, 102D) either in a continuous uninterrupted movement, or with a temporary stop at one or more processing positions (102A, 102B, 102C, 102D). The four dotted arrows in FIG. 1A illustrate the general direction of movement of each substrate 101. While only one substrate 101 is illustrated in FIGS. 1A AND 1B, embodiments are expressly contemplated herein in which multiple substrates, such as two substrates, three substrates, or four substrates, are located into the reactor system 1000.

While the present disclosure is described employing a reactor system including four processing spaces (100, 200, 300, 400) and four purge spaces (150, 250, 350, 450), embodiments are expressly contemplated herein in which N processing spaces and N purge spaces are arranged to form an alternating sequence of processing spaces and purge spaces in which each processing space is followed by a purge space, and each purge space is followed by a processing space, and the last space of the alternating sequence is connected to the first space of the alternating sequence. The number N can be an integer greater than 2. For example, the number N can be in a range from 2 to 10, such as from 3 to 6, although greater numbers can also be employed.

In one embodiment, the first subset (100, 200, 300, 400) of the multiple partitions can include at least one precursor treatment space (such as the first processing space 100 and the third processing space 300) configured to flow a respective precursor gas that provides precursor gas species which adsorb to a material on a substrate therein, and at least one reaction space (such as the second processing space 200 and the fourth processing space 400) configured to flow a respective process gas (e.g., reactant gas) selected from a nitridant, an oxidant, and a reduction gas and configured to form a material layer including atoms from the respective precursor gas. For example, the at least one precursor treatment space can include a first precursor treatment space (embodied as the first processing space 100) and a second precursor treatment space (embodied as a third processing space 300). The at least one reaction space (200, 400) can include a first reaction space (embodied as a second processing space 200) and a second reaction space (embodied as a fourth processing space 400). The first reaction space (embodied as the second processing space 200) can be configured to flow a first process gas that forms a first material layer over a substrate therein upon reaction with a first precursor gas species adsorbed from the first precursor treatment space. The second reaction space (embodied as the fourth processing space 400) can be configured to flow a second process gas that forms a second material layer over a substrate therein upon reaction with a second precursor gas species adsorbed from the second precursor treatment space.

In one embodiment, the reactor system 1000 can be configured to form an alternating stack of instances of a first material layer and instances of a second material layer by performing multiple repetitions of the cyclic pattern. In one cyclic pattern, each substrate 101 moves through the entire set of partitions (100, 200, 300, 400, 150, 250, 350, 450) once and returns to a starting position. In case multiple substrates are employed, each substrate 101 other than a substrate 101 positioned in a partition that provides a first processing environment for deposition of a target material stack can be subjected to an inert gas flow during passage through a subset of the partitions (100, 200, 300, 400, 150, 250, 350, 450) until each substrate 101 arrives at the partition that provides the first processing environment for deposition of the target material stack. In one embodiment, the cyclic pattern can include an alternating pattern in which each processing space (100, 200, 300, 400) is followed by a respective purge space (150, 250, 350, 450) and each purge space (150, 250, 350, 450) is followed by a respective processing space (200, 300, 400), or is a last space in the cyclic pattern.

Beginning from the partition that provides the first processing environment for deposition of the target material stack (which can be the first processing space 100, for example), each repetition of the cyclic pattern forms a respective instance of the first material layer and a respective instance of the second material layer. In one embodiment, one of the first material layer and the second material layer can be an insulating material layer, and another of the first material layer and the second material layer can be a conductive material layer.

In one embodiment, an alternating stack of insulating layers and conductive material layers can be formed employing atomic layer deposition (ALD) processes, such as thermal ALD or plasma enhanced ALD. The insulating layers can be deposited employing a combination of the first precursor treatment space 100 that provides a first precursor gas for forming an insulating material (such as an aluminum-containing precursor for aluminum oxide deposition or a silicon-containing precursor for silicon oxide or nitride deposition) and a first reaction space 200 that is configured to flow a first process gas (which may be, for example, an oxidant such as oxygen or ozone, or a nitridant gas, such as ammonia, nitrogen or hydrazine) that forms an insulating layer (such as an aluminum oxide, silicon oxide or silicon nitride layer) over a substrate upon reaction with the first precursor gas species adsorbed from the first precursor treatment space 100 and remain adsorbed during passage through the first purge space 150. The conductive material layers can be deposited employing a combination of the second precursor treatment space 300 that provides a second precursor gas for forming a conductive material (such as a tungsten-containing precursor for tungsten or tungsten nitride deposition, or a titanium-containing precursor for titanium or titanium nitride deposition) and a second reaction space 400 that is configured to flow a second process gas (which may be, for example, a reducing agent such as hydrogen, silane, or diborane for tungsten or titanium deposition, or a nitridant such as ammonia, nitrogen or hydrazine for titanium nitride or tungsten nitride deposition) that forms the conductive material layer (such as a tungsten, titanium, TiN or WN layer) over a substrate upon reaction with the second precursor gas species adsorbed from the second precursor treatment space 300 and remain adsorbed during passage through the third purge space 350.

In one embodiment, reactor system 2000 can employ a silicon-organic or a metal organic precursor. Non-limiting examples of semiconductor, conductive or insulating materials that can be deposited employing the exemplary reactor systems of the present disclosure include: titanium or titanium nitride (which may be formed by employing Tetrakis(dimethylamido)titanium(IV) (“TDMAT”), tetrakis(ethylmethylamido)titanium (“TEMAT”) or any other suitable methyl, ethyl, carbonyl or amide-containing precursor as a precursor gas followed by reaction with a nitridant reaction gas such as ammonia, nitrogen or hydrazine to form TiN); tantalum nitride (which may be formed by employing tert-butylimidotris(diethylamido)tantalum (“TBTDET”) as a precursor gas followed by reaction with a nitridant such as ammonia); tungsten (which may be formed by employing W(CO)₆ or any suitable methyl, ethyl, carbonyl or amide-containing precursor as a precursor gas), molybdenum (which may be formed by employing Mo(CO)₆ or any suitable methyl, ethyl, carbonyl or amide-containing precursor as a precursor gas), cobalt (which may be formed by employing dicobalt hexacarbonyl tert-butylacetylene (“CCTBA”) or any suitable methyl, ethyl, carbonyl or amide-containing precursor as a precursor gas), aluminum nitride or oxide (which may be formed by employing trimethyl aluminum (“TMA”) or any suitable methyl, ethyl, carbonyl or amide-containing precursor as a precursor gas), hafnium oxide (which may be formed by employing hafnium tert-butoxide (“HTB”) or tetrakis diethylamido hafnium (“TDEAH”) as a precursor gas), silicon, silicon nitride or silicon oxide (which may be formed using a silicon precursor such as (N,N-dimethylamino)trimethylsilane, vinyltrimethoxysilane, trivinylmethoxysilane, tetrakis(dimethylamino)silane or tris(dimethylamino)silane (“TDMAS”), followed by a reaction with a nitridant or oxidant to form silicon nitride or silicon oxide), lanthanum oxide, or zirconium oxide.

In one embodiment, each purge space (150, 250, 350, 450) can be configured to induce directional movement of a respective purge gas therein. For example, the at least one respective purge gas inlet 70 and the respective vacuum port 80 in each purge space (150, 250, 350, 450) can be laterally spaced along the direction of movement of the at least one substrate carrier within the reactor system 1000. In one embodiment, each purge gas flow pattern can include a first lateral flow path that is along the direction of movement of the at least one substrate carrier (e.g., along the clockwise azimuthal direction in FIG. 1A or the direction to the right in FIG. 1B) and a second lateral flow path that is against the direction of movement of the at least one substrate carrier (e.g., along the counterclockwise azimuthal direction in FIG. 1A or the direction to the left in FIG. 1B).

In one embodiment, the at least one of the processing spaces (100, 200, 300, 400) in the first subset of the multiple partitions (100, 200, 300, 400, 150, 250, 350, 450) can include one or more process gas distribution manifolds (110, 210, 310, 410) configured to flow a process gas toward a substrate while the substrate passes under the respective process gas distribution manifold (110, 210, 310, 410). In one embodiment, one of more of the process gas distribution manifolds (110, 210, 310, 410) can include a showerhead. The process gas can be a reactant that deposits a material upon decomposition in case a chemical vapor deposition process is employed, or can include a reactant such as a nitridant, oxidant or a reducing agent in case an atomic layer deposition process is employed.

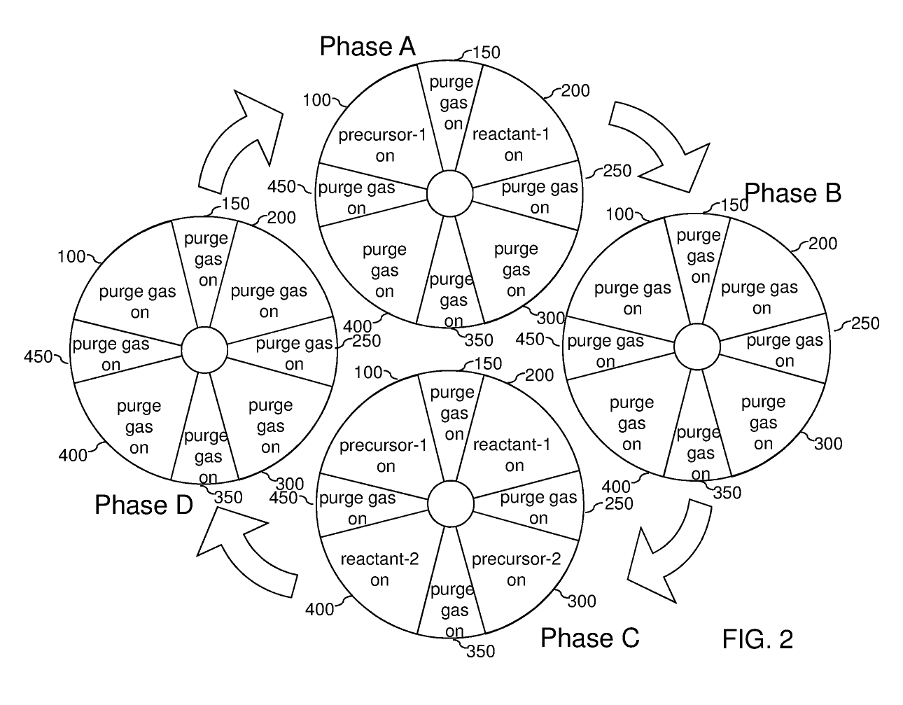

FIG. 2 is a diagram illustrating an exemplary set of phases that can be employed to operate the reactor system of FIGS. 1A and 1B. FIG. 2 illustrates operation of the reactor system 1000 for the case in which the at least one substrate carrier is a single substrate carrier configured to carry only a single substrate 101. The reactor system 1000 can cycle through multiple phases within each processing cycle. For example, each processing cycle can include phase A in which the substrate 101 travels through the first precursor treatment space 100, the first purge space 150, and the first reaction space 200. The first precursor gas (or “precursor-1”) can remain turned on while the substrate 101 passes through the first precursor treatment space 100 and into the first purge space 150, and the first process gas (“reactant-1”) can be turned on while the substrate 101 passes through the first reaction space 200. The second precursor treatment space 300 and the second reaction space 400 can be configured to flow a respective purge gas (e.g., nitrogen or argon) therein while the single substrate carrier is in the first precursor treatment space 100 or in the first reaction space 200.

Each processing cycle can include phase B in which the substrate 101 travels through the second purge space 250. In phase B, all partitions (100, 200, 300, 400, 150, 250, 350, 450) can flow respective purge gases.

Each processing cycle can include phase C in which the substrate 101 travels through the second precursor treatment space 300, the third purge space 350, and the second reaction space 400. The second precursor gas (or “precursor-2”) can remain turned on while the substrate 101 passes through the second precursor treatment space 200 and into the third purge space 350, and the second process gas (“reactant-2”) can be turned on while the substrate 101 passes through the second reaction space 400. The first precursor treatment space 100 and the second reaction space 200 can be configured to flow a respective purge gas therein while the single substrate carrier is in the second precursor treatment space 300 or in the second reaction space 400.

Each processing cycle can include phase D in which the substrate 101 travels through the fourth purge space 450. In phase D, all partitions (100, 200, 300, 400, 150, 250, 350, 450) can flow respective purge gases. Phases A through D can be sequentially performed within a processing cycle, which can be employed to form a stack of a first material layer and a second material layer. In one embodiment, the stack can include an insulating layer and a conductive material layer.

Referring back to FIGS. 1A and 1B, the reactor system 1000 can be operated by loading at least one substrate 101 into the reactor system 1000, and by depositing at least one film on each of the at least one substrate by moving the at least one substrate through each of the multiple partitions in the cyclic pattern employing the sequence.

In one embodiment, a respective precursor gas that provides precursor gas species that adsorb to a material on a substrate can be flowed in at least one precursor treatment space (which can be, for example, the first processing space 100 and/or the third processing space 300) among the first subset (100, 200, 300, 400) of the multiple partitions. A respective process gas (i.e., reactant gas) selected from a nitridant, an oxidant, and a reduction gas can be flowed in at least one reaction space (which can be, for example, the second processing space 200 and/or the fourth processing space 400) among the first subset (100, 200, 300, 400) of the multiple partitions to form a material layer including atoms from the respective precursor gas.

In one embodiment, the at least one precursor treatment space can include a first precursor treatment space (which can be embodied as the first processing space 100) and a second precursor treatment space (which can be embodied as the third processing space 300), and the at least one reaction space can include a first reaction space (which can be embodied as the second processing space 200) and a second reaction space (which can be embodied as the fourth processing gas 400). In this configuration, operation of the reactor system 100 can include, within a single processing cycle, the steps of: (a) adsorbing a first precursor gas species to a first surface on the substrate in the first precursor treatment space, (b) flowing a first process gas that forms a first material layer upon reaction with the first precursor gas species in the first reaction space, (c) adsorbing a second precursor gas species to a second surface on the substrate in the second precursor treatment space, and (d) flowing a second process gas that forms a second material layer upon reaction with the second precursor gas species in the second reaction space.

By repeatedly performing the processing cycle employing the reactor system 1000 of the present disclosure, an alternating stack of instances of the first material layer and instances of the second material layer can be fabricated. In one embodiment, the second material layer can be the same as the first material layer to enable formation of a thick homogeneous film. In one embodiment, the processing steps can include atomic layer deposition processes for deposition of a same material throughout each cycle.

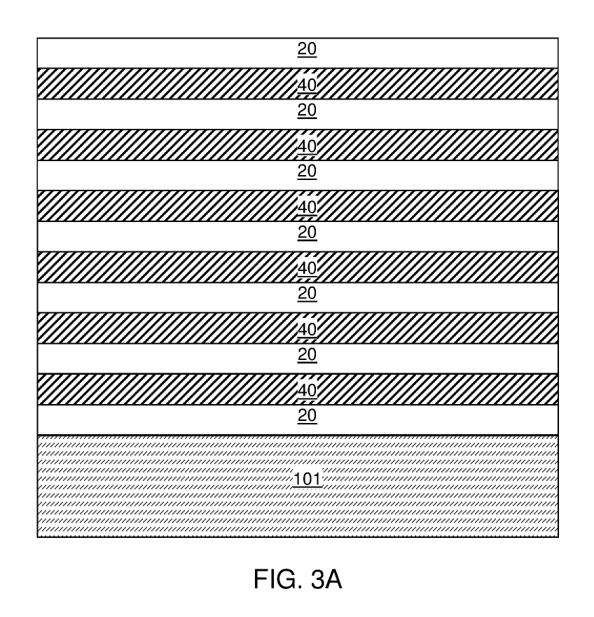

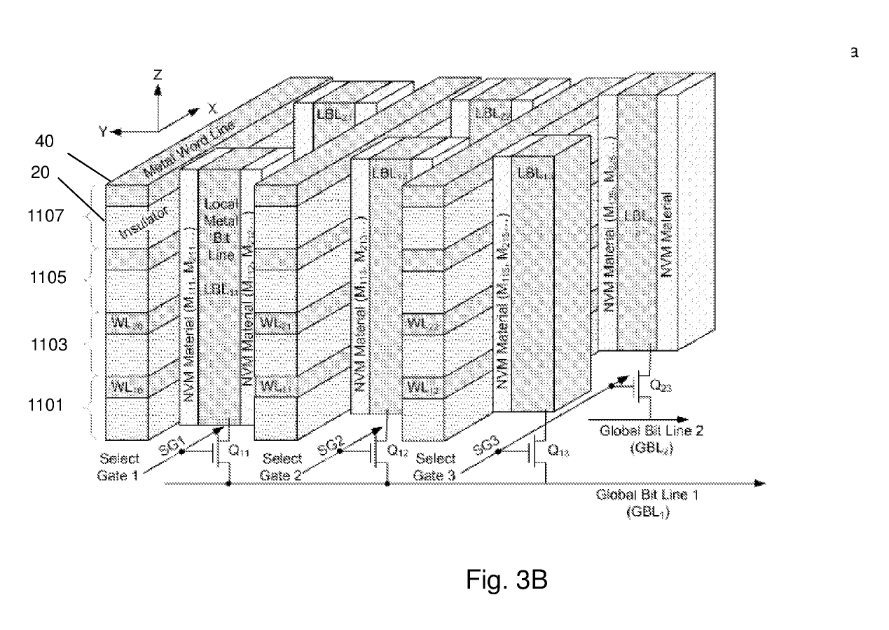

In another embodiment, the second material layer includes a different material than the first material layer. FIG. 3A is a vertical cross-sectional view of an exemplary film stack that can be formed employing the reactor system of FIGS. 1A and 1B in case the second material layer includes a different material from the first material layer. For example, an alternating stack of first material layers 20 and second material layers 40 can be formed over a substrate 101.

As used herein, an alternating stack of first elements and second elements refers to a structure in which instances of the first elements and instances of the second elements alternate. Each instance of the first elements that is not an end element of the alternating plurality is adjoined by two instances of the second elements on both sides, and each instance of the second elements that is not an end element of the alternating plurality is adjoined by two instances of the first elements on both ends. The first elements may have the same thickness thereamongst, or may have different thicknesses. The second elements may have the same thickness thereamongst, or may have different thicknesses. The alternating plurality of first material layers and second material layers may begin with an instance of the first material layers or with an instance of the second material layers, and may end with an instance of the first material layers or with an instance of the second material layers. In one embodiment, an instance of the first elements and an instance of the second elements may form a unit that is repeated with periodicity within the alternating plurality.

In one embodiment, the thickness of each layer within the alternating stack (20, 40) may be in a range from 10 nm to 100 nm, although lesser and greater thicknesses can also be employed. In one embodiment, an alternating stack of insulating layers 20 (such as silicon oxide, silicon nitride or aluminum oxide layers) and electrically conductive layers 40 (such as tungsten, WN, titanium or TiN layers) can be formed for resistive random access memory (ReRAM) applications. In another embodiment, an alternating stack of insulating layers (such as silicon oxide layers) and sacrificial material layers (such as silicon nitride layers, amorphous silicon layers, polysilicon layers, or silicon-germanium alloy layers) can be formed for three-dimensional NAND memory applications. In another embodiment, an alternating stack of insulating layers (such as silicon oxide layers) and conductive material layers (such as tungsten layers or heavily doped semiconductor layers) can be formed for three-dimensional NAND memory applications.

For example, the alternating stack of insulating layers 20 (e.g., silicon oxide, silicon nitride, etc.) and electrically conductive layers 40 (e.g., W, TiN, etc.) of FIG. 3A may be incorporated into the monolithic, three dimensional ReRAM memory device shown in FIG. 3B. The memory cells of such devices may be vertically oriented, such that at least one memory cell is located over another memory cell. The array allows vertical scaling of the devices to provide a higher density of memory cells per unit area of silicon or other semiconductor material.

FIG. 3B shows one example of vertically oriented three dimension ReRAM memory device having vertical bit lines of the type described in U.S. Pat. Pub. No. 2012/0147648, published Jun. 14, 2012 and incorporated by reference herein in its entirety. The ReRAM device is configured for use of non-volatile memory element (“NVM”) material that is non-conductive when first deposited. Since the material is initially non-conductive, there is no necessity to isolate the memory elements at the cross-points of the word and bit lines from each other. Several memory elements may be implemented by a single continuous layer of material, which in the case of FIG. 3B are strips of NVM material oriented vertically along opposite sides of the vertical bit lines in the x-direction and extending upwards through all the planes in the z-direction. A significant advantage of the structure of FIG. 3B is that all word lines and insulating layers under them in a group of planes may be defined simultaneously by use of a single mask, thus greatly simplifying the manufacturing process.

Referring to FIG. 3B, a small part of four planes (e.g., device levels separated in the z-direction) 1101, 1103, 1105 and 1107 of the three-dimensional array are shown. Each plane (i.e., device level) contains one insulating layer 20 and one electrically conductive layer 40 which functions as a word line of a memory cell. All of the planes have the same horizontal pattern of conductive, insulating and NVM materials. In each plane, electrically conductive (e.g., metal) word lines 40 (WL_{zx}) are elongated in the y-direction and spaced apart in the x-direction. Each plane includes a layer of insulating material 20 (e.g., a dielectric) that isolates its word lines from the word lines of the plane below it or, in the case of plane 1101, of the substrate circuit components below it. In some embodiments, the word lines WL_{zx} for a fixed value of x form a stack of alternating layers that may extend beyond the memory device into a contact area (not shown).

Extending through each plane is a collection of electrically conductive (e.g., metal or metal nitride, such as TiN) local bit line (LBL) “pillars” elongated in the vertical z-direction and forming a regular array in the x-y planes. The LBL pillars and the NVM material are formed by patterning the alternating stack (20, 40) to form a plurality of openings followed by forming the NVM material and the LBL pillars in the openings.

Each bit line pillar is connected to one of a set of underlying global bit lines (GBL) (e.g., located in the silicon substrate) running in the x-direction at the same pitch as the pillar spacing through the select devices (Q_{yx}) formed in the substrate whose gates are driven by the row select lines (SG) elongated in the y-direction, which are also formed in the substrate. The select devices Q_{yx} may be vertically oriented field effect transistors. Examples of suitable transistors for the select devices Q_{yx} are described, for example, in U.S. patent application Ser. No. 14/206,196, filed Mar. 12, 2014, which is incorporated by reference herein in its entirety. Also fabricated in the substrate but not shown in FIG. 3B are sense amplifiers, input-output (I/O) circuitry, control circuitry, and any other necessary peripheral circuitry. There is one row select line (SG) for each row of local bit line pillars in the y-direction and one select device (Q) for each individual local bit line (LBL).

Each vertical strip of NVM material is sandwiched between the vertical local bit lines (LBL) and a plurality of word lines (WL) vertically stacked in all the planes. Preferably the NVM material is present between the local bit lines (LBL) in the y-direction. A memory storage element (M) is located at each intersection of a word line (WL) and a local bit line (LBL). In the case of a metal oxide (e.g., nickel oxide or copper oxide) for the memory storage element material, a small region of the NVM material between an intersecting local bit line (LBL) and word line (WL) is controllably alternated between more conductive (set) and less conductive (reset) states by appropriate voltages applied to the intersecting lines.

The material used for the non-volatile memory elements M_{zyx} in the array of FIG. 3B can be a metal oxide (e.g., hafnium oxide, titaniumtitaniurn oxide, etc.), a carbon material, a chalcogenide (e.g., a chalcogenide glass such as GeₓS_{y}Te_{z}, where preferably x=2, y=2 and z=5, GeSb, AgInSbTe, GeTe, GaSb, BaSbTe, InSbTe, etc.) a solid electrolyte, or any one of a number of materials that exhibit a stable, reversible shift in resistance in response to an external voltage applied to or current passed through the material.

The reactor system 1000 is a deposition system employing a single chamber for deposition of a stack of repeated material compositions or continuous deposition of a same material (in case the partitions are configured to deposit the same material). Employing a single chamber including multiple partitions, each substrate is sequentially subjected to a first process gas flow (such as the gas flows from the first and second processing spaces (100, 200)) that induces deposition of a first material (such as an insulator material), a first purge gas flow (such as a purge gas flow in the second purge space 250), a second process gas flow (such as the gas flows from the third and fourth processing spaces (300, 400)) that induces deposition of a second material (such as a metallic material, a semiconductor material, or another insulating material that is a sacrificial material), and a second purge gas flow (such as the gas flow in the fourth purge space 450).

The reactor system 1000 enables deposition of an alternating stack of first material layers 20 and second material layers 40 within a single continuous vacuum enclosure without moving a substrate 101 outside a vacuum environment. Mixing of process gases between processing spaces (100, 200, 300, 400) is prevented or reduced by employing gas separation regions as embodied as purge spaces (150, 250, 350, 450). In case an alternating stack of insulating layers 20 (such as silicon oxide layers) and electrically conductive layers (such as tungsten layers, tungsten nitride layers, titanium layers, titanium nitride layers, cobalt layers, or ruthenium layers) is formed, formation of metal impurity in the insulating layers is minimized due to separation of the process gases. In one embodiment, the number of repetitions in the alternating stack can be the same as the number of repetitions of the process cycle.

The reactor system 1000 can be modified to add additional processing spaces and additional purge spaces to increase the number of processing steps in each process cycle during which the substrate 101 makes a single revolution around a rotation axis, or can be modified to remove a subset of processing spaces and purge spaces.

In one embodiment, the reactor system 1000 can be modified to remove precursor treatment spaces and purge spaces configured to receive a substrate from precursor treatment spaces. For example, the first and third processing spaces (100, 300) and the first and third purge spaces (150, 350) can be removed from the reactor system 1000, and the second and fourth processing spaces (200, 400) and the second and fourth purge spaces (250, 450) may be present in a modified reactor system. In this case, the second and fourth processing spaces (200, 400) can perform respective deposition processes (such as chemical vapor deposition (CVD) processes) that do not require use of an adsorbed gas species.

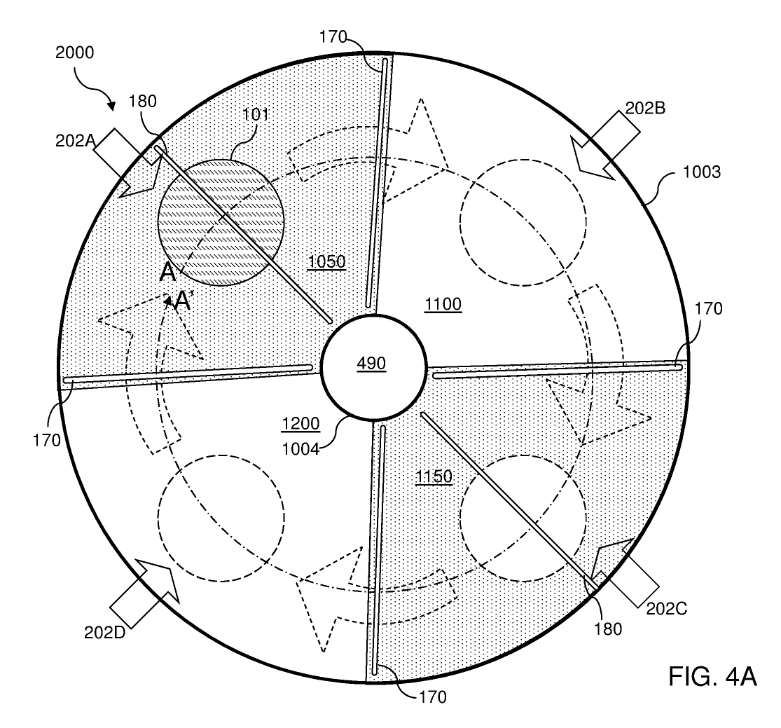

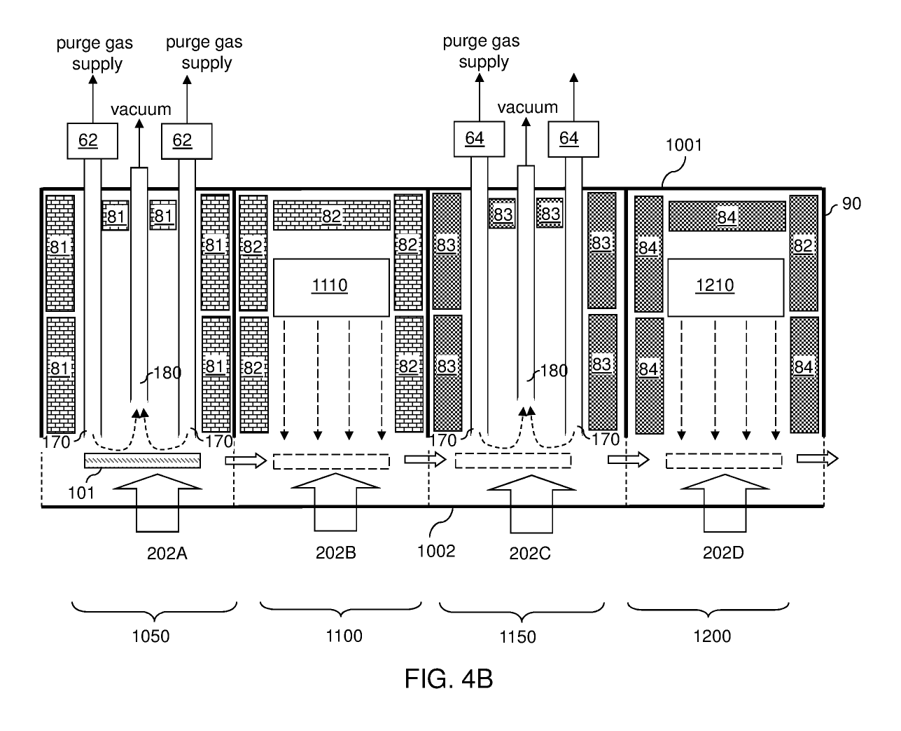

Referring to FIGS. 4A and 4B, the first exemplary reactor system 1000 can be modified to remove two processing spaces and two purge spaces to provide a second exemplary reactor system 2000. The second exemplary reactor system 2000 can be provided with independent temperature control capabilities in at least one of the partitions.

For example, the second exemplary reactor system 2000 can include a single process chamber including multiple partitions (1100, 1200, 1050, 1150) for at least one substrate 101 to travel through. Each substrate 101 can be affixed (for example, by gravity or electrostatic force) to a respective substrate carrier (such as a chuck) that travels cyclically through the multiple partitions. The reactor system 2000 includes a vacuum enclosure, which can be a vacuum-tight space. In one embodiment, the vacuum enclosure can be connected to at least one vacuum pump, and can be configured to maintain a base pressure less than 100 mTorr, and preferably less than 1 mTorr, and even more preferably less than 1.0×10⁻⁶ Torr in the absence of any gas flow therein.

As in the first exemplary reactor system 1000, the vacuum enclosure may be defined by a combination of a top enclosure plate 1001 and a bottom enclosure plate 1002 that are vertically spaced from each other and adjoined to an outer sidewall 1003. Optionally, an inner sidewall 1004 extending between the top enclosure plate 1001 and the bottom enclosure plate 1002 can be provided within the outer sidewall 1003. In this case, the vacuum enclosure can be topologically homeomorphic to a torus. In case the inner sidewall 1004 is not present, the vacuum enclosure can be topologically homeomorphic to a sphere. In this case, a vacuum pump may be connected to a center portion of the vacuum enclosure.

Optionally, substantially vertical sidewalls 90 that extend only partially between the top enclosure plate 1001 and the bottom enclosure plate 1002 can be provided. The substantially vertical sidewalls 90 may be adjoined to the top enclosure plate 1001 and not adjoined to the bottom enclosure plate 1002, or may be adjoined to the bottom enclosure plate 1002 and not adjoined to the top enclosure plate 1001. In this case, the partitions may be defined by the substantially vertical sidewalls 90 that extend vertically by distances that are less than the vertical spacing between the top enclosure plate 1001 and the bottom enclosure plate 1002. Gaps are provided between each neighboring pair of partitions for passage of the at least one substrate carrier and the at least one substrate thereupon. Each of the multiple partitions is defined by respective distinct volumes within the single continuous vacuum enclosure that are connected thereamongst for unhindered movement of at least one substrate therethrough.

In one embodiment, the reactor system 2000 can include a substrate carrier rotation mechanism 490 configured to rotate the at least one substrate carrier around a rotation axis located in a center portion of the reactor system. The multiple partitions can be located at different azimuthal angles around the rotation axis without any door or valve between neighboring pairs of partitions.

The multiple partitions (1100, 1200, 1050, 1150) can include a first subset that includes processing spaces (1100, 1200) and a second subset that includes purge spaces (1050, 1150). Each of the processing spaces (1100, 1200) is a partition configured to provide a respective process gas that provides a process selected from adsorption or reaction (e.g., nitridation, oxidation or reduction). For example, the processing spaces (1100, 1200) can include a first processing space 1100 configured to perform an adsorption process and a second processing space 1200 configured to perform a reaction process (e.g., nitridation, oxidation or reduction). Each of the purge spaces (1050, 1150) can be configured to provide a respective purge gas flow pattern therein between at least one respective purge gas inlet 170 and a respective vacuum port 180. Each of the at least one purge gas inlet 170 can be connected to a flow control device 62, 64 which may be a mass flow controller (MFC) or an automatically actuated on/off valve. Each flow control device can be connected to a purge gas supply, which can be a source of an inert gas such as argon or nitrogen. Each of the purge spaces (1050, 1150) can be configured to provide isolation between process gases between a respective neighboring pair of processing spaces (1100, 1200).

The purge spaces (1050, 1150) provide gas separation between neighboring pairs of processing spaces (1100, 1200), thereby preventing mixing of the process gases from neighboring processing spaces (1100, 1200). The substrate travels within a single chamber that defines a single continuous vacuum enclosure. In one embodiment, no door or valve is present within the single continuous vacuum enclosure, and the separation of process environment among the positions can be provided by the purge gas (such as argon or nitrogen gas) and the vacuum pumping at the gas separation areas.

In one embodiment, a single substrate carrier (e.g., a chuck) supporting a single substrate is employed within the process chamber. In another embodiment, multiple substrate carriers (e.g., multiple chucks) each supporting a respective substrate can be employed in the process chamber to process multiple substrates.

The at least one substrate carrier can be configured to sequentially move through each of the multiple partitions in a cyclic pattern employing a sequence in which the processing spaces (1100, 1200) alternate with the purge spaces (1050, 1150). For example, the purge spaces (1050, 1150) can include a first purge space 1050 located between the first processing space 1100 and the second processing space 1200, and a second purge space 1150 located between the second processing space 1200 and the first processing space 1100.

Each processing space (1100, 1200) can include a respective processing position (202A, 202C) for processing a substrate 101. Each purge space (1050, 1150) can include a respective processing position (202B, 202D) for exposing the substrate 101 to a respective purge gas. A single substrate 101 or a plurality of substrates 101 can be loaded into the vacuum enclosure through an opening in the top enclosure plate 1001, though an opening in the bottom enclosure plate 1002, or through the outside sidewall 1003. The opening for passing one or more substrates 101 can be a valve that can provide a vacuum seal between the vacuum enclosure and the surrounding volume. Each substrate 101 can move through the various processing positions (102A, 102B, 102C, 102D) either in a continuous uninterrupted movement, or with a temporary stop at one or more processing positions (102A, 102B, 102C, 102D). The four dotted arrows in FIG. 4A illustrate the general direction of movement of each substrate 101. While only one substrate 101 is illustrated in FIGS. 4A and 4B, embodiments are expressly contemplated herein in which multiple substrates, such as two substrates, three substrates, or four substrates, are located into the reactor system 2000.

In one embodiment, the first subset (1100, 1200) of the multiple partitions can include a precursor treatment space (such as the first processing space 1100) configured to flow a precursor gas that provides species which adsorb to a material on a substrate therein, and a reaction space (such as the second processing space 1200) configured to flow a process gas selected from a nitridant, an oxidant, and a reduction gas and configured to form a material layer including atoms from the respective precursor gas. The reaction space (embodied as the second processing space 1200) can be configured to flow a process gas that forms a material layer over a substrate therein upon reaction with the precursor gas species adsorbed from the precursor treatment space.

In one embodiment, the reactor system 2000 can be an atomic layer deposition (ALD) system in which the substrate 101 moves through each of the partitions (1100, 1200, 1050, 1150) in a sequential order in a cyclic pattern. In one embodiment, the cyclic pattern can include an alternating pattern in which each processing space (1100, 1200) is followed by a respective purge space (1050, 1150) and each purge space (1050, 1150) is followed by a respective processing space (1100, 1200), or is a last space in the cyclic pattern.

In one embodiment, each purge space (1050, 1150) can be configured to induce directional movement of a respective purge gas therein. For example, the at least one respective purge gas inlet 170 and the respective vacuum port 180 in each purge space (1050, 1150) can be laterally spaced along the direction of movement of the at least one substrate carrier within the reactor system 2000. In one embodiment, each purge gas flow pattern can include a first lateral flow path that is along the direction of movement of the at least one substrate carrier (e.g., along the clockwise azimuthal direction in FIG. 4A or the direction to the right in FIG. 4B) and a second lateral flow path that is against the direction of movement of the at least one substrate carrier (e.g., along the counterclockwise azimuthal direction in FIG. 4A or the direction to the left in FIG. 4B).

In one embodiment, the at least one of the processing spaces (1100, 1200) in the first subset of the multiple partitions (1100, 1200, 1050, 1150) can include one or more process gas distribution manifolds (1110, 1210) configured to flow a process gas toward a substrate while the substrate passes under the respective process gas distribution manifold (1110, 1210). In one embodiment, one of more of the process gas distribution manifolds (1110, 1210) can include a showerhead. The process gas can be a reactant that deposits a material upon decomposition in case a chemical vapor deposition process is employed, or can include a reactant such as a nitridant, oxidant or a reducing agent in case an atomic layer deposition process is employed.

While the present disclosure is described employing an embodiment in which the reactor system 2000 includes one precursor treatment space and one reaction space, embodiments are expressly contemplate herein in which at least one additional precursor treatment space and/or at least one additional reaction space is present in the reactor system. Thus, the system of FIGS. 1A and 1B containing eight partitions may include the temperature control elements of FIGS. 4A and 4B.

One or more of the partitions (1100, 1200, 1050, 1150) can include a temperature control element (81, 82, 83, 84). As used herein, a “temperature control element” refers to any element that can generate heat or remove heat to alter the temperature of the ambient around the element. As such, a temperature control element can be a heater or a cooling device.

The at least one temperature control element (81, 82, 83, 84) in the partitions (1100, 1200, 1050, 1150) can provide differential temperatures between the two processing steps performed at the first processing space 1100 and the second processing space 1200. For example, adsorption of a gas can be more effective at a lower temperature (such as at room temperature or below room temperature, including zero to less than 25 degrees Celsius), and reaction (deposition, oxidation, or reduction) can be more effective at an elevated temperature (such as a temperature of at least 100 degrees Celsius, such as 100 to 350 degrees Celsius).

Generally speaking, a first temperature control element 82 can be located in a heat transfer relationship with (e.g., in, on or adjacent to) one of the at least one precursor treatment space (such as the first processing space 1110), and can be configured to maintain the at least one substrate 101 at a first temperature during adsorption of the respective precursor gas species. A second temperature control element 84 can be located in a heat transfer relationship with one of the at least one reaction space (such as the second processing space 1210), and can be configured to maintain the at least one substrate 101 at a second temperature during formation of the material layer including atoms from the precursor gas. Additionally, a first purge temperature control element 81 can be located in a heat transfer relationship with a first purge space 1050, and a second purge temperature control element 83 can be located in a heat transfer relationship a second purge space 1150. Each of the temperature control elements (81, 82, 83, 84) may be located within a respective partition (1100, 1200, 1050, 1150) or outside the respective partition (1100, 1200, 1050, 1150), or may straddle a sidewall, a top surface, or a bottom surface of the respective partition (1100, 1200, 1050, 1150).

The temperature differential between the first temperature and the second temperature may be in a range from 10 degrees Celsius to 600 degrees Celsius, and may be in a range from 50 degrees to 300 degrees. In one embodiment, the second temperature is higher than the first temperature by at least 50 degrees Celsius, and may be higher than the first temperature by at least 100 degrees Celsius.

In one embodiment, the first temperature control element 82 and the first purge temperature control element 81 can include a respective a cooling system (such as at least one water-cooled panel), and the second temperature control element 84 and the second purge temperature control element 83 can include a respective a heating system (such as at least one electrical heater).

A first purge space 1050 among the purge spaces (1050, 1150) can be configured to forward the at least one substrate carrier directly to the one of the at least one precursor treatment space (such as the first processing space 1100), and can be configured to flow a first purge gas at a first purge gas temperature. The first purge gas temperature may be the same as the first temperature of the first processing space 1100, or may be lower than the first temperature of the first processing space 1100 to provide accelerated cooling of a substrate 101 while passing through the first purge space 1050. Alternatively, the first purge gas temperature may be above the first process temperature and below the second process temperature in case a slow cooling of the substrate 101 is desired.

A second purge space 1150 among the purge spaces (1050, 1150) can be configured to forward the at least one substrate carrier directly to one the of the at least one reaction space, and can be configured to provide a second purge gas at a second purge gas temperature that is higher than the first purge gas temperature. The second purge gas temperature may be the same as the second temperature of the second processing space 1200, or may be higher than the second temperature of the second processing space 1200 to provide accelerated heating of a substrate 101 while passing through the second purge space 1150. Alternatively, the second purge gas temperature may be above the first process temperature and below the second process temperature in case a slow heating of the substrate 101 is desired.

In one embodiment, the first purge gas temperature can be below 25 degrees Celsius, such as 0 to 20 degrees Celsius, and the second purge gas temperature can be above 60 degrees Celsius, above 100 degrees Celsius, and/or above 200 degrees Celsius, such as 100 to 350 degrees Celsius.

Each substrate 101 can be cooled to the first temperature while the substrate 101 is present in a respective precursor treatment space (such as the first processing space 1100) that is configured to provide adsorption of a gas at the first temperature prior to, or during, adsorption of a precursor gas species on the substrate 101. Each substrate 101 can be heated to the second temperature while the substrate 101 is present in a respective reaction space (such as the second processing space 1200) that is configured to form a material layer therein prior to, or during, formation of the material layer.

In one embodiment, a first purge gas can be flowed at a first purge gas temperature to cool the substrate 101 in a first purge space 1050 among the purge spaces (1050, 1150). The first purge temperature can be lower than, or can be the same as, the first temperature of the first processing space 1100. Alternatively, the second purging temperature can be between the first temperature and the second temperature in case slow cooling of the substrate 101 is desired. The cooled substrate 101 can be forwarded from the first purge space 1050 to the one of the at least one precursor treatment space (such as the first precursor treatment space embodied as the first processing space 1100). Temperature stabilization at the first temperature in the precursor treatment space can be accelerated due to cooling of the substrate 101 by the first purge gas. Lateral flow of the first purge gas increases the effectiveness of cooling by the first purge gas. The precursor gas species can be easily adsorbed on surfaces of materials on the substrate 101 at the first temperature, which is a lower temperature than the second temperature of reaction. This is because most metal-organic precursors have high adsorption efficiency at a low temperature. The precursor gas species can be uniformly adsorbed even on structures having a high aspect ratio or located within recessed regions. Self-decomposition of the precursor gas is minimized due to the low temperature provided in the precursor adsorption space.

Once adsorption of the precursor gas species is complete, the substrate 101 is passed into a second purge space 1150. A second purge gas can be flowed at a second purge gas temperature to heat the substrate 101 in a second purge space 1150 among the purge spaces (1050, 1150). The second purge temperature can be higher than, or can be the same as, the second temperature of the second processing space 1200. Alternatively, the second purging temperature can be between the first temperature and the second temperature in case slow heating of the substrate 101 is desired. Most of the adsorbed precursor gas species remains on the surfaces of materials on the substrate 101 as the substrate 101 passes through the second purge space 1100. The heated substrate 101 can be forwarded from the second purge space 1150 to the one of the at least one reaction space (such as the first reaction space embodied as the second processing space 1200). The second temperature is high enough to induce reaction between the adsorbed precursor gas species and the process gas supplied in the second processing space 200, which can be a nitridant, an oxidant, or a reducing agent. Upon formation of a material layer, the substrate 101 is passed to the first purge space 101 to be cooled and to start a new processing cycle.

The second exemplary reactor system 2000 can be employed as an atomic layer deposition system. Each processing cycle can correspond to one deposition cycle of an atomic layer deposition process, and can form a layer of a deposited material. The processing cycles can be repeated to form at least one film on the substrate 101, which may be a homogeneous film having a same composition throughout.

The exemplary reactor systems 1000, 2000 may produce an alternating stack of different material layers (e.g., an alternating stack of insulating layers 20 and electrically conductive layers 40) using a single chamber ALD apparatus. Little or no gas mixing occurs between partitions by using the purge gas separation areas, which reduces or avoids metal impurities in the insulating layers 20. Furthermore, the systems provide a high process throughput since the substrate does not have to pass through load locks between deposition of layers in the alternating stack. The second exemplary reactor system 2000 can provide high throughput and conformal material deposition even on high aspect ratio structures due to the enhanced adsorption at low temperature. The cooling spaces (such as the first purge space 1050 and the first processing space 1100) can cool the substrate 101 prior to adsorption to enhance conformity of the adsorbed process gas. Upon heating and movement into a reaction space, the deposition process proceeds without losing the benefit of conformal surface coverage of the adsorbed gas molecules, which react with the process gas provided in the reaction space to form a conformal material layer.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

1. A reactor system comprising multiple partitions within a single continuous vacuum enclosure, wherein:
each of the multiple partitions is defined by respective distinct volumes within the single continuous vacuum enclosure that are connected thereamongst for unhindered movement of at least one substrate therethrough;
a first subset of the multiple partitions comprise processing spaces configured to provide a respective process gas that provides a process selected from adsorption and reaction;
a second subset of the multiple partitions comprising purge spaces configured to provide a respective purge gas flow pattern therein between at least one respective purge gas inlet and a respective vacuum port and to provide isolation between process gases between a respective neighboring pair of processing spaces; and
at least one substrate carrier is configured to sequentially move through each of the multiple partitions in a cyclic pattern employing a sequence in which the processing spaces alternate with the purge spaces.

2. The reactor system of claim 1, wherein the first subset of the multiple partitions comprises:
at least one precursor treatment space configured to flow a respective precursor gas that provides a precursor gas species which adsorb to a material on a substrate therein; and
at least one reaction space configured to flow a respective process gas selected from a nitridant, an oxidant, and a reduction gas and configured to form a material layer including atoms from the respective precursor gas.

3. The reactor system of claim 2, wherein:
the at least one precursor treatment space comprises a first precursor treatment space and a second precursor treatment space;
the at least one reaction space comprises a first reaction space and a second reaction space;
the first reaction space is configured to flow a first process gas that forms a first material layer over a substrate therein upon reaction with a first precursor gas species adsorbed from the first precursor treatment space; and
the second reaction space is configured to flow a second process gas that forms a second material layer over a substrate therein upon reaction with a second precursor gas species adsorbed from the second precursor treatment space.

4. The reactor system of claim 3, wherein:
the reactor system is configured to form an alternating stack of instances of the first material layer and instances of the second material layer by performing multiple repetitions of the cyclic pattern; and
each repetition of the cyclic pattern forms a respective instance of the first material layer and a respective instance of the second material layer.

5. The reactor system of claim 4, wherein:
one of the first material layer and the second material layer is an insulating material layer; and
another of the first material layer and the second material layer is a conductive material layer.

6. The reactor system of claim 3, wherein:
the at least one substrate carrier comprises a single substrate carrier;
the first reaction space is configured to flow a first purge gas therein while the single substrate carrier is in the second reaction space; and
the second reaction space is configured to flow a second purge gas therein while the single substrate carrier is in the first reaction space.

7. The reactor system of claim 2, further comprising:
a first temperature control element located in a heat transfer relationship with one of the at least one precursor treatment space and configured to maintain the at least one substrate at a first temperature during adsorption of the respective precursor gas species; and
a second temperature control element located a heat transfer relationship with one of the at least one reaction space and configured to maintain the at least one substrate at a second temperature during formation of the material layer including atoms from the respective precursor gas species.

8. The reactor system of claim 7, wherein the second temperature is higher than the first temperature by at least 50 degrees Celsius.

9. The reactor system of claim 7, wherein:
the first temperature control element comprises a cooling system; and
the second temperature control element comprises a heating system.

10. The rector system of claim 7, wherein:
a first purge space among the purge spaces is configured to forward the at least one substrate carrier directly to the one of the at least one precursor treatment space, and is configured to flow a first purge gas at a first purge gas temperature; and
a second purge space among the purge spaces is configured to forward the at least one substrate carrier directly to one the of the at least one reaction space, and is configured to provide a second purge gas at a second purge gas temperature that is higher than the first purge gas temperature.

11. The rector system of claim 10, wherein:
the first purge gas temperature is below 25 degrees Celsius; and
the second purge gas temperature is above 60 degrees Celsius.

12. The reactor system of claim 1, wherein:
the at least one respective purge gas inlet and the respective vacuum port are laterally spaced along a direction of movement of the at least one substrate carrier within the reactor system; and
each purge gas flow pattern includes a first lateral flow path that is along the direction of movement of the at least one substrate carrier and a second lateral flow path that is against the direction of movement of the at least one substrate carrier.

13. The reactor system of claim 1, further comprising a substrate carrier rotation mechanism configured to rotate the at least one substrate carrier around a rotation axis located in a center portion of the reactor system, wherein the multiple partitions are located at different azimuthal angles around the rotation axis without any door or valve between neighboring pairs of partitions.

14. The reactor system of claim 13, wherein:
the reactor system comprises a top enclosure plate and a bottom enclosure plate that are vertically spaced from each other and adjoined to an outer sidewall to define the single continuous vacuum enclosure; and
the partitions are defined by substantially vertical sidewalls that extend vertically by distances that are less than a vertical spacing between the top enclosure plate and the bottom enclosure plate to provide gaps for passage of the at least one substrate carrier and the at least one substrate thereupon.

15. The reactor system of claim 1, wherein at least one of the processing spaces in the first subset of the multiple partitions comprises a process gas distribution manifold including a showerhead configured to flow a process gas toward a substrate while the substrate passes under the process gas distribution manifold.

16. The reactor system of claim 1, wherein:
the reactor system comprises an atomic layer deposition system; and
the cyclic pattern comprises an alternating pattern in which each processing space is followed by a respective purge space and each purge space is followed by a respective processing space, or is a last space in the cyclic pattern.

17. A method of operating a reactor system, comprising:
loading at least one substrate into the reactor system of claim 1; and
depositing at least one layer on each of the at least one substrate by moving the at least one substrate through each of the multiple partitions in the cyclic pattern employing the sequence in which the processing spaces alternate with the purge spaces.

18. The method of claim 17, further comprising:
flowing a respective precursor gas that provides precursor gas species which adsorb to a material on a substrate in at least one precursor treatment space among the first subset of the multiple partitions; and
flowing a respective process gas selected from a nitridant, an oxidant, and a reduction gas in at least one reaction space among the first subset of the multiple partitions to form a material layer including atoms from the respective precursor gas.

19. The method of claim 18, wherein:
the at least one precursor treatment space comprises a first precursor treatment space and a second precursor treatment space;
the at least one reaction space comprises a first reaction space and a second reaction space; and
the method further comprises:
adsorbing a first precursor gas species to a first surface on the substrate in the first precursor treatment space;
flowing a first process gas that forms a first material layer upon reaction with the first precursor gas species in the first reaction chamber;
adsorbing a second precursor gas species to a second surface on the substrate in the second precursor treatment space; and
flowing a second process gas that forms a second material layer upon reaction with the second precursor gas species in the second reaction chamber.

20. The method of claim 19, further comprising forming an alternating stack of instances of the first material layer and instances of the second material layer, wherein the second material layer includes a different material than the first material layer.

21. The method of claim 20, wherein the first material layers comprise insulating layers and the second material layers comprise electrically conductive word lines of a three-dimensional ReRAM memory device.

22. The method of claim 18, further comprising:
cooling the substrate to a first temperature while the substrate is present in one of the at least one precursor treatment space prior to, or during, adsorption of the precursor gas species on the substrate; and
heating the substrate to a second temperature while the substrate is present in one of the at least one reaction space prior to, or during, formation of the material layer.

23. The method of claim 22, further comprising:
flowing a first purge gas at a first purge gas temperature to cool the substrate in a first purge space among the purge spaces;
forwarding the cooled substrate from the first purge space to the one of the at least one precursor treatment space;
flowing a second purge gas at a second purge gas temperature to heat the substrate in a second purge space among the purge spaces; and
forwarding the heated substrate from the second purge space to the one of the at least one reaction space, wherein the at least one film is a homogeneous film having a same composition throughout.

23. (canceled)

24. A method of making a device, comprising:
loading a substrate into a chamber of reactor system; and
depositing by atomic layer deposition an alternating stack of instances of a first material layer and instances of a second material layer different from the first material layer on the substrate by moving the substrate through multiple processing spaces and purge spaces in the chamber in a cyclic pattern employing sequence in which the processing spaces alternate with the purge spaces.

25. The method of claim 26, further comprising:
flowing a first precursor gas that provides first precursor gas species which adsorb to a material on a substrate in a first processing space among the processing spaces; and
flowing a first process gas selected from a nitridant, an oxidant, and a reduction gas in a second processing space among the processing spaces to form a first material layer including atoms from the first precursor gas.

26. The method of claim 25, further comprising:
adsorbing a second precursor gas species to the first material layer on the substrate in a third processing space among the processing spaces; and
flowing a second process gas selected from a nitridant, an oxidant, and a reduction gas in a fourth processing space among the processing spaces to form the second material layer including atoms from the second precursor gas

27. The method of claim 26, wherein the first material layers comprise insulating layers and the second material layers comprise electrically conductive word lines of a three-dimensional ReRAM memory device.

28. The method of claim 25, further comprising:
cooling the substrate to a first temperature while the substrate is present in the first processing space prior to, or during, adsorption of the precursor gas species on the substrate; and
heating the substrate to a second temperature while the substrate is present in the second processing space prior to, or during, formation of the first material layer.

29. The method of claim 28, further comprising:
flowing a first purge gas at a first purge gas temperature to cool the substrate in a first purge space among the purge spaces;
forwarding the cooled substrate from the first purge space to the first processing space;
flowing a second purge gas at a second purge gas temperature to heat the substrate in a second purge space among the purge spaces; and
forwarding the heated substrate from the second purge space to the second processing space.
